(19) United States
(12) Patent Application Publication
(10) Pub. No.: US 2007/0063306 A1
(43) Pub. Date: Mar. 22, 2007

(54) Multiple crystal orientations on the same substrate

(75) Inventors: Brian S. Doyle, Portland, OR (US); Jack Kavalieros, Portland, OR (US); Justin K. Brask, Portland, OR (US); Suman Datta, Beaverton, OR (US); Robert S. Chau, Beaverton, OR (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/234,014

(22) Filed: Sep. 22, 2005

(51) Int. Cl. H01L 27/095

(52) U.S. Cl. 257/486; 257/E31.04; 257/E29.004

(57) ABSTRACT

Embodiments of the invention provide a substrate with a surface having different crystal orientations in different areas. Embodiments of the invention provide a substrate with a portion having a <100> crystal orientation and another portion having a <110> crystal orientation. N— and P-type devices may both be formed on the substrate, with each type of device having the proper crystal orientation for optimum performance.

### BACKGROUND

1. Background of the Invention

Many integrated circuits, such as microproccesors, make use of N— and P-MOS transistors formed on the same substrate. NMOS transistors function better on a substrate with a <100> crystal orientation. PMOS transistors, in contrast, function better on a substrate with a <110> crystal orientation.

### BRIEF DESCRIPTION OF THE DRAWINGS

FIG. 1a is a cross sectional side view that illustrates the semiconductor device of one embodiment of the present invention.

FIG. 1b is a perspective view that illustrates the semiconductor device of one embodiment of the present invention.

FIG. 1c is a perspective view that illustrates the different crystal orientations of the bodies of the device layer of the SOI substrate in more detail.

FIG. 2 is a cross sectional side view that illustrates an SOI substrate with a device layer having a <100> crystal orientation.

FIG. 3 is a cross sectional side view that illustrates a second SOI substrate with a device layer having a <110> crystal orientation according to one embodiment.

FIG. 4 is a cross sectional side view that illustrates the two SOI substrates bonded together.

FIG. 5 is a cross sectional side view that illustrates the SOI substrates after the carrier substrate and insulator layer have been removed, leaving a single SOI substrate with two stacked device layers.

FIG. 6 is a cross sectional side view that illustrates how a portion of the first device layer may be amorphized according to one embodiment of the present invention.

FIG. 7 is a cross sectional side view that illustrates how a portion of the second device layer may be amorphized according to one embodiment of the present invention.

FIG. 8 is a cross sectional side view that shows the substrate after amorphizing portions of the first and second device layers, according to one embodiment.

FIG. 9 is a cross sectional side view that shows the substrate after the amorphized portions have been partially recrystallized.

FIG. 10 is a cross sectional side view that illustrates the substrate after the amorphized regions have been recrystallized.

FIG. 11 is a cross sectional side view that illustrates the substrate after the semiconductor layer has been thinned.

FIG. 12 is a cross sectional side view that illustrates the substrate after fins have been defined, on which tri-gate transistors may be formed.

FIG. 13 is a cross sectional side view that illustrates one such device that includes planar transistor on a device layer having portions with different crystal orientations, according to another embodiment of the present invention.

FIG. 14 illustrates a system in accordance with one embodiment of the present invention.

### DETAILED DESCRIPTION

In various embodiments, an apparatus and method relating to the formation of a substrate are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

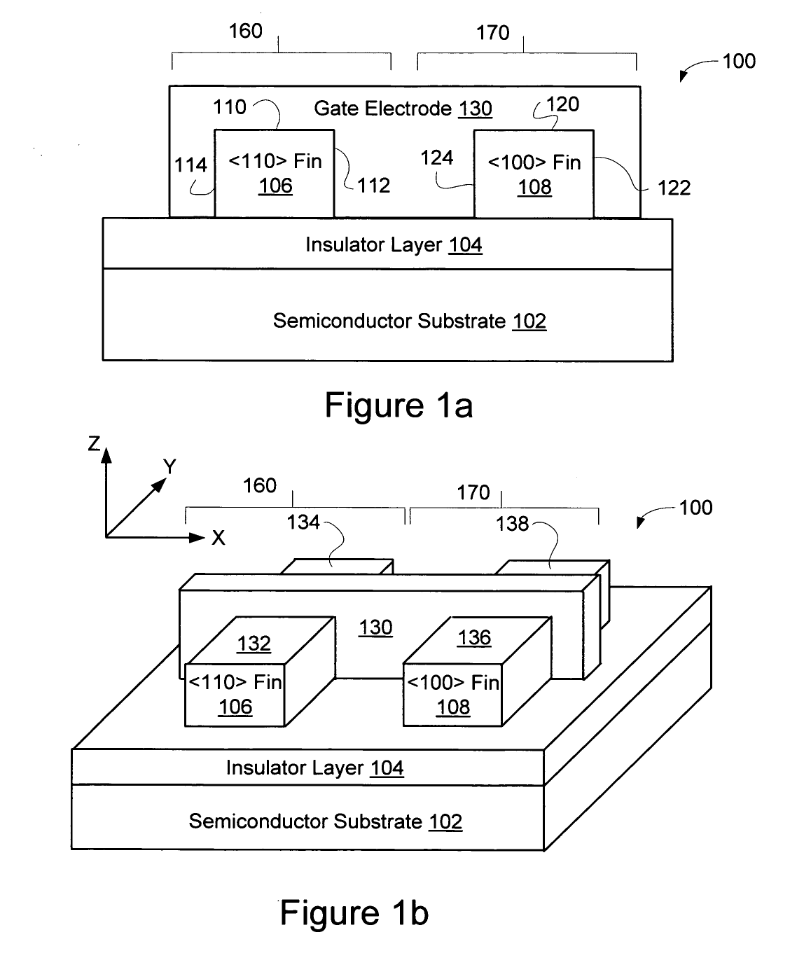

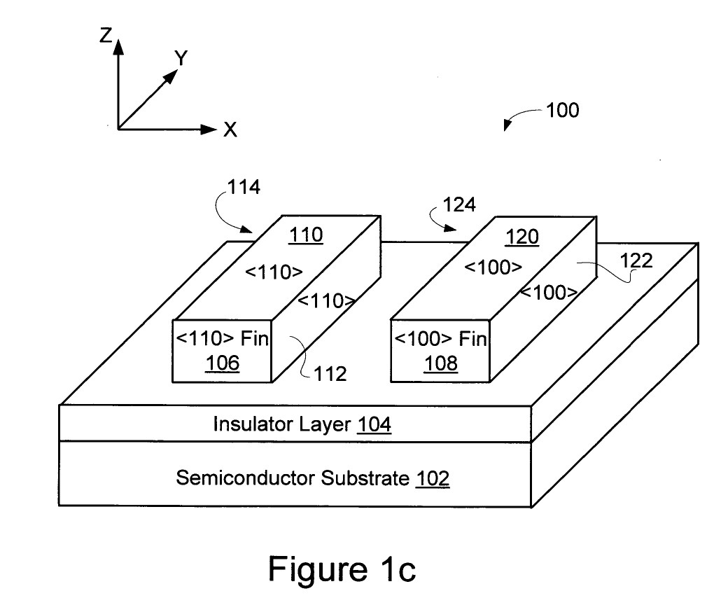

FIG. 1a is a cross sectional side view that illustrates a semiconductor device 100 according to one embodiment of the present invention. FIG. 1b is a perspective view that illustrates the semiconductor device 100 of one embodiment of the present invention. In an embodiment, the device 100 may include tri-gate transistors on a substrate with a buried insulating layer. The substrate with buried insulator layer may have a device layer with multiple different crystal orientations.

In the embodiment shown in FIGS. 1a and 1b, two tri-gate transistors 160, 170 (one PMOS 160 and one NMOS 170) are formed on a semiconductor on insulator (SOI) substrate. Each of tri-gate transistors 160, 170 includes a silicon body 106, 108 formed on insulator layer 104 on a single crystal silicon semiconductor substrate 102. Bodies 106, 108 of the illustrated embodiment are in the form of fins defined from a silicon device layer of the SOI substrate. A gate dielectric layer (not shown) is formed on the top 110, 120 and sidewalls 112, 114, 122, 124 of the silicon bodies 106, 108, between the bodies 106, 108 and gate electrode 130. A gate electrode 130 is formed on the gate dielectric layer and surrounds the bodies 106, 108 on three sides. The gate 130 essentially provides transistors 160, 170 with three gate electrodes, one on each of the sidewalls 112, 114, 122, 124 of the silicon bodies 106, 108 and one on the top surfaces 110, 120 of the silicon bodies 106, 108. Source regions 132, 136 and drain regions 134, 138 are formed in silicon bodies 106, 108 on opposite sides of gate electrode 130 as shown in FIG. 1b. The active channel region is the region of the silicon body located beneath gate electrode 130 and between the source regions 132, 136 and drain regions 134, 138.

In other embodiments, the device 100 may be a different type of device. For example, rather than a single electrode 130 on two bodies 106, 108, each body 106, 108 may have a separate gate electrode 130. The device may be a different type of transistor, such as a planar transistor, a FIN-FET transistor, or a different type of transistor or other device 100.

The semiconductor substrate 102 may be a silicon substrate, such as single crystal silicon, a different type of semiconductor material, or a combination of materials. The insulator layer 104 may be a layer of oxide, such as silicon oxide, or another type of insulating material. The bodies 106, 108 may be considered portions of a device layer, or portions of a second semiconductor layer on the insulator layer 104. The device layer may comprise silicon, a different type of semiconductor material, or a combination of materials. In an embodiment, the device layer, and thus the bodies 106, 108 may comprise single crystal silicon. In combination, the semiconductor substrate 102, insulator layer 104, and device layer may be considered a semiconductor on insulator substrate (SOI), where each device, such as transistors 160, 170, may be isolated electrically from other devices on the substrate by the insulator layer 104. Although transistors 160, 170 may include portions of the device layer of the SOI substrate (in the form of bodies 106, 108), the transistors 160, 170 are still considered to be “on” the SOI substrate.

As shown in the illustrated embodiment, the PMOS transistor 160 may be formed with a body 106 having a <110> crystal orientation and the NMOS transistor 170 may be formed with a body 108 having a <100> crystal orientation. Thus, the bodies 106, 108 of this embodiment are portions of the device layer of the SOI substrate having different crystal orientations; different portions of the SOI substrate have different crystal orientations. In the illustrated embodiment, the different crystal orientations are <100> and <110>, although other orientations may be present in other embodiments.

FIG. 1c is a perspective view that illustrates the different crystal orientations of the bodies 106, 108 of the device layer of the SOI substrate in more detail. The bodies 106, 108 may be fins isolated from each other in some embodiments.

In the embodiment illustrated in FIG. 1c, body 106 is a <110> fin where each of the top 110 and sidewalls 112, 114 has a <110> crystal orientation. Thus, the top 110 surface of body 106 has a <110> plane which lies in the x̅y̅ plane with a normal axis in the z direction. Similarly, the sidewall 112 of body 106 has a <110> plane which lies in the z̅y̅ plane with a normal axis in the x direction, as does the sidewall 114. Having all three sides of the tri-gate channel of the transistor 160 with this <110> crystal orientation allows for increased mobility of holes and high performance of the p-type transistor 160.

In the embodiment illustrated in FIG. 1c, body 108 is a <100> fin where each of the top 120 and sidewalls 122, 124 has a <100> crystal orientation. Thus, the top 120 surface of body 108 has a <100> plane which lies in the x̅y̅ plane with a normal axis in the z direction. Similarly, the sidewall 122 of body 108 has a <100> plane which lies in the z̅y̅ plane with a normal axis in the x direction, as does the sidewall 124. Having all three sides of the tri-gate channel of the transistor 170 with this <100> crystal orientation allows for increased mobility of electrons and high performance of the n-type transistor 170.

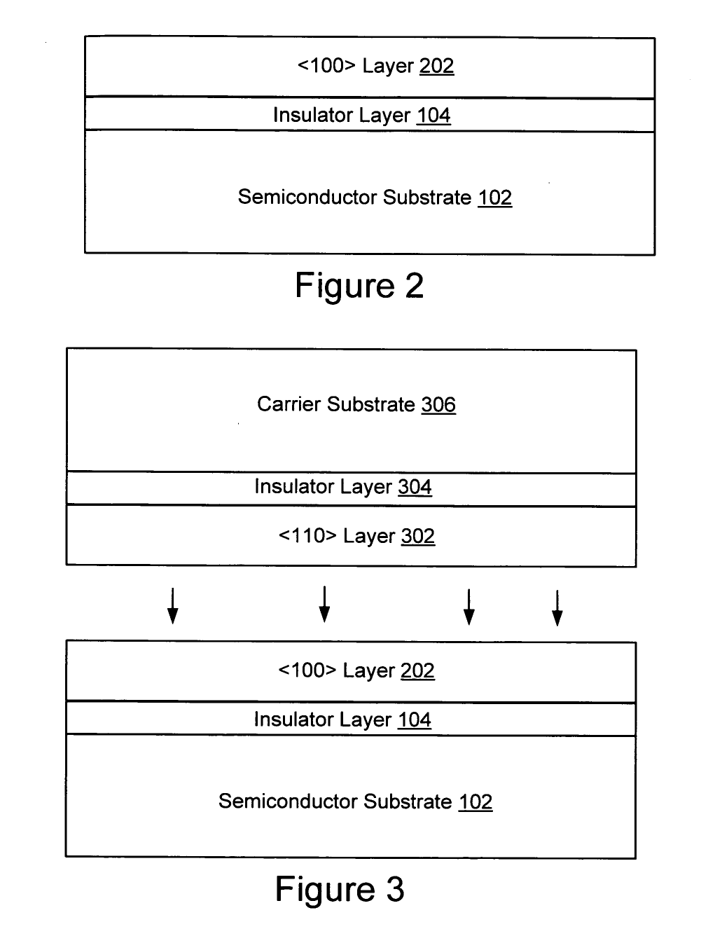

FIGS. 2 through 11 are cross sectional side views that illustrate how an SOI substrate with portions (also referred to as regions) of the top semiconductor layer (also referred to as the device layer) having different crystal orientations may be made according to one embodiment.

FIG. 2 is a cross sectional side view that illustrates an SOI substrate with a device layer having a <100> crystal orientation according to one embodiment. The SOI substrate may include a semiconductor substrate 102 (also referred to as a base layer of semiconductor material), which may comprise silicon or another semiconducting material or combination of materials. An insulator layer 104 may be a layer of oxide, such as silicon oxide, or another type of insulating material, and may also be known as a buried oxide layer. The top layer 202 (also referred to as a device layer) of the SOI substrate may comprise silicon or another semiconducting material or combination of materials. The top layer 202 may have a crystal orientation. In the illustrated embodiment, the top layer 202 has a <100> crystal orientation (with a top surface having a <100> plane with a normal axis pointing up in FIG. 2), although other embodiments may have other crystal orientations. In an embodiment, the crystal orientation of the top layer 202 may be chosen to be one of the crystal orientations desired to be present in the final device 100. Thus, to result in the device 100 of FIG. 1, the crystal orientation of the top layer 202 may be chosen to be <100> or <110> in some embodiments.

FIG. 3 is a cross sectional side view that illustrates a second SOI substrate with a device layer having a <110> crystal orientation according to one embodiment. The arrows indicate the second SOI substrate is being brought into contact with the first SOI substrate. The second SOI substrate may include a carrier substrate 306, which may comprise silicon or another semiconducting material or combination of materials. An insulator layer 304 may be a layer of oxide, such as silicon oxide, or another type of insulating material, and may also be known as a buried oxide layer. The device layer 302 of the second SOI substrate may comprise silicon or another semiconducting material or combination of materials.

The device layer 302 may have a crystal orientation. In the illustrated embodiment, the device layer 302 has a <110> crystal orientation (with a bottom surface in the Figure having a <110> plane with a normal axis pointing down in FIG. 3), although other embodiments may have other crystal orientations. In an embodiment, the crystal orientation of the device layer 302 may be chosen to be the crystal orientation desired to be present in the final device 100 and not present in the top layer 202 of the first SOI substrate. Thus, to result in the device 100 of FIG. 1, the crystal orientation of the device layer 302 may be chosen to be <110> for a top layer 202 having a <100> crystal orientation. In another embodiment, top layer 202 may have a <110> crystal orientation and device layer 302 may have a <100> crystal orientation. In yet other embodiments, different crystal orientations may be chosen for the top layer 202 and device layer 302, to result in a final SOI substrate having a device or top semiconductor layer with different portions or regions with different desired crystal orientations.

The second SOI substrate may be brought into contact with the first SOI substrate and the top layer 202 bonded to the device layer 302 in an embodiment. In an embodiment, both of the top layer 202 and device layer 302 may comprise single crystal silicon, although in other embodiments they may comprise other materials.

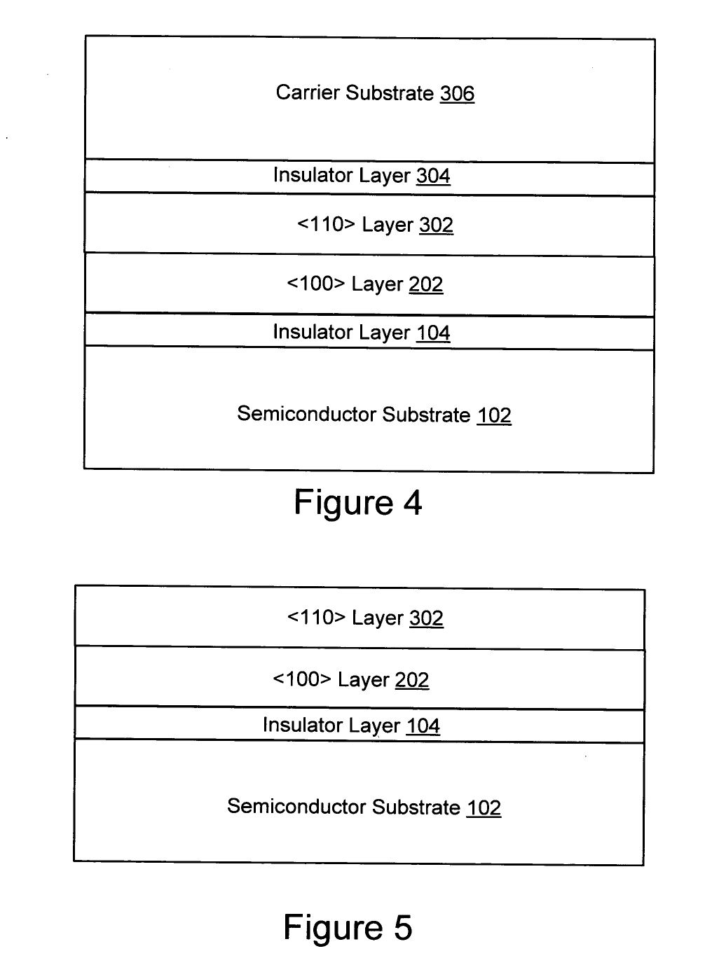

FIG. 4 is a cross sectional side view that illustrates the two SOI substrates bonded together. In an embodiment where the top layer 202 and device layer 302 comprise silicon, there may be a silicon-to-silicon bond connecting the two SOI substrates. In other embodiments, such as embodiments where the top layer 202 and device layer 302 comprise different materials, the bonding may be different.

FIG. 5 is a cross sectional side view that illustrates the SOI substrates after the carrier substrate 306 and insulator layer 304 have been removed, leaving a single SOI substrate with two stacked device layers 202, 302. The SOI substrate includes a semiconductor substrate 102, an insulator layer 104, and two device layers 202, 302, each with a different crystal orientation. Carrier substrate 306 and insulator layer 304 may be removed by any suitable method.

While the SOI substrate with two device layers 202, 302 with different crystal orientations is described above as formed from two separate SOI substrates bonded together and then the carrier substrate 306 and insulator layer 304 removed, it may be formed differently in different embodiments. For example, a second device layer 302 that is not part of an SOI substrate may be bonded or formed on the first device layer 202.

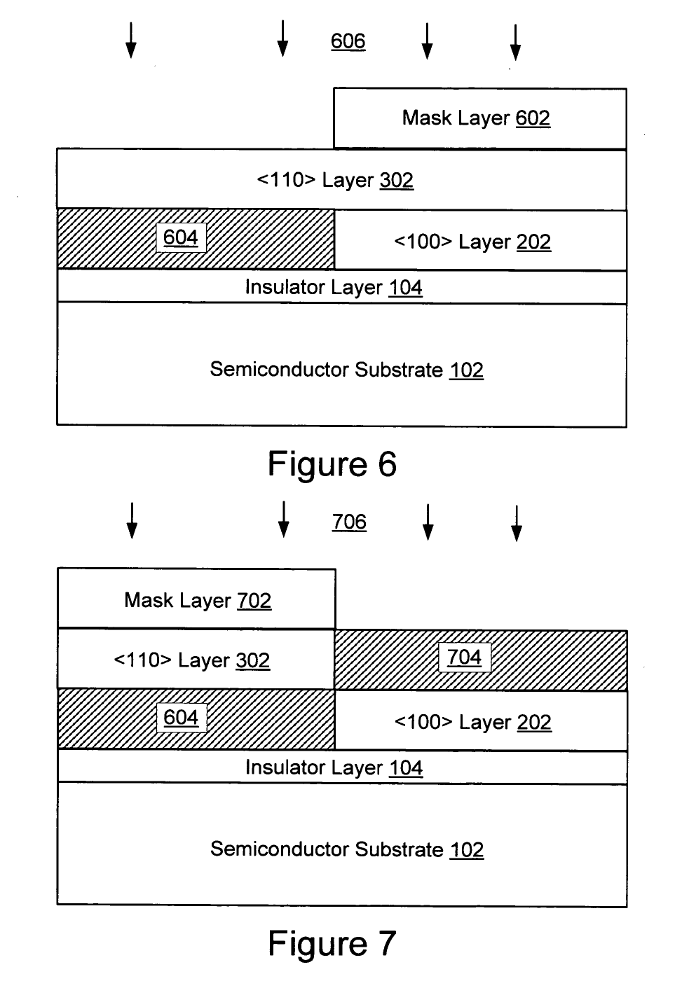

FIG. 6 is a cross sectional side view that illustrates how a portion of the first device layer 202 may be amorphized according to one embodiment of the present invention. A mask layer 602 may protect portions of the first device layer 202 that will not be amorphized. The mask layer 602 may be, for example, a patterned layer of photoresist material. Ions 606 may be implanted through the second device layer 302 into the first device layer 202 to amorphize the former crystal structure of the first device layer 202, creating an amorphized portion 604 of the first device layer 202. Thus, the <100> crystal structure of a portion of layer 202 may be changed to an amorphous structure. In an embodiment where the first device layer 202 comprises silicon, arsenic, germanium, or silicon ions 606 may be implanted into the first device layer, although other ions may be implanted. In some embodiments, the dopants 606 may be about the same size or a little bit larger than the atoms that make up the first device layer 202. The dopants 606 may be neutral, or may n- or p-type dopants.

In an embodiment, the doping may be done with silicon ions having an energy in the range of 6-8 keV and a dose of 1×10¹⁴ to 1×10¹⁵ atoms/cm², and in another embodiment the doping may be done at about 7 keV and a dose of about 5×10¹⁴ atoms/cm². Other ions and other process conditions may be used in other embodiments.

FIG. 7 is a cross sectional side view that illustrates how a portion of the second device layer 302 may be amorphized according to one embodiment of the present invention. A mask layer 702 may protect portions of the second device layer 302 that will not be amorphized. The mask layer 702 may be, for example, a patterned layer of photoresist material. Ions 706 may be implanted into the second device layer 302 to amorphize the former crystal structure of the second device layer 302, creating an amorphized portion 704 of the second device layer 302. Thus, the <110> crystal structure of a portion of layer 302 may be changed to an amorphous structure. In an embodiment where the second device layer 302 comprises silicon, arsenic, germanium, or silicon ions 706 may be implanted into the first device layer, although other ions may be implanted. In some embodiments, the implanted ions 706 may be about the same size or a little bit larger than the atoms that make up the second device layer 302. The dopants 706 may be neutral, or may n- or p-type dopants. In an embodiment, the dopants 706 used to amorphize a portion of the second device layer 302 may be the same dopants 606 used to amorphize a portion of the first device layer 202.

In an embodiment, the doping may be done with germanium ions having an energy in the range of 65-75 keV and a dose of 1×10¹³ to 1—10¹⁴ atoms/cm², and in another embodiment, the doping may be done at about 70 keV and a dose of about 6×10¹³ atoms/cm². Other ions and other process conditions may be used in other embodiments.

The dopants 606, 706 may both be an n- or p-type dopant in some embodiments. If such dopants are used, doping used to make transistors may compensate for the dopants already present. For example, if an n-type dopant 606 is used and a p-type transistor is formed on that portion of the substrate, extra p-type dopants may be used when making the transistor than would be used absent the doping steps described with respect to FIGS. 6 and 7. In other embodiments, the dopants 606, 706 may be chosen to correctly dope the substrate for one or more of the later-formed devices. Both dopants 606, 706 may be the same and may correctly dope the substrate for one type (n- or p-) of device in one embodiment. In this embodiment, the other type of device may need extra doping later to compensate. In another embodiment, dopants 606, 706 may be different and each chosen to correctly dope the substrate; dopant 606 may be a p-type dopant and dopant 706 may be an n-type dopant, or vice versa.

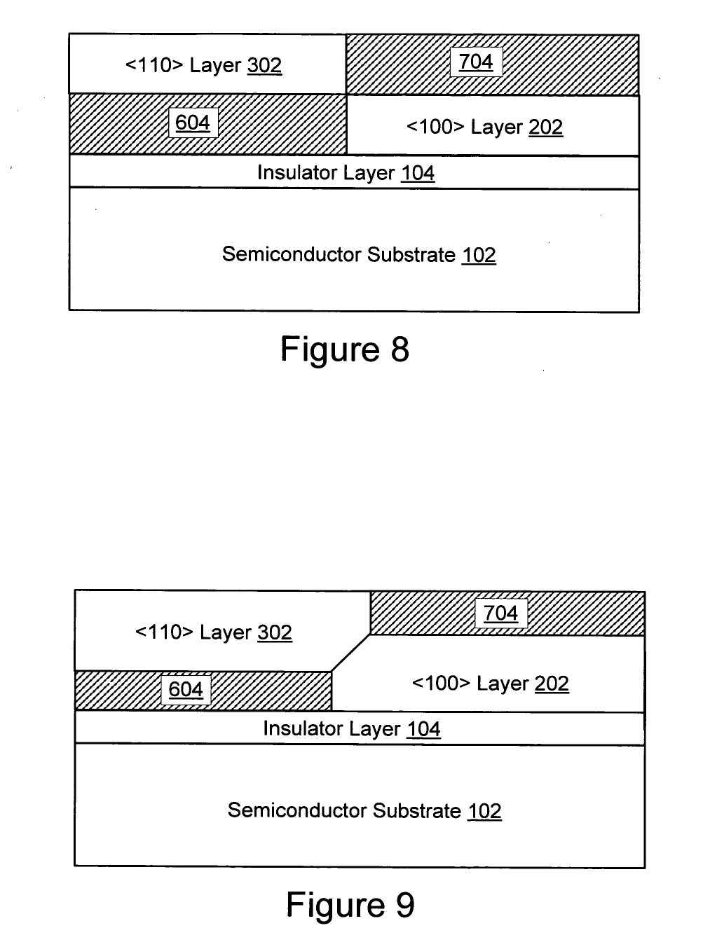

FIG. 8 is a cross sectional side view that shows the substrate after amorphizing portions of the first and second device layers 202, 302, according to one embodiment. In the illustrated embodiment, a portion of the <110> layer 302 retains its <110> crystal orientation, while a portion 704 has been amorphized. A portion of the <100> layer 202 retains its <100> crystal orientation, while a portion 604 has been amorphized. While the amorphizing process has been illustrated and described as first amorphizing the first device layer 202 and then the second device layer 302, this order may be reversed in other embodiments.

FIG. 9 is a cross sectional side view that shows the substrate after the amorphized portions 604, 704 have been partially recrystallized, according to one embodiment. In an embodiment, the amorphized portions 604, 704 may be recrystallized by annealing the substrate. The amorphized portions 604, 704 may recrystallize with the atoms having the same crystal orientation as the orientation of the non-amorphized portion to which the formerly amorphous section is adjacent. For example, the left-hand side of amorphized region 704 is adjacent to layer 302 with a <110> crystal orientation. Thus, the left-hand side of amorphized region 704 will have a <110> crystal orientation and become part of<110> layer 302. Similarly, the bottom of amorphized region 704 is adjacent to layer 202 with a <100> crystal orientation. Thus, the bottom of amorphized region 704 will have a <100> crystal orientation and become part of <100> layer 202. This results in the diagonal boundary between the device layers 202, 302. While illustrated as a sharp boundary, there may be instead a region between the layers 202, 302 in which the crystal orientation is neither wholly <100> nor <110>.

In an embodiment, the substrate may be annealed at a temperature between about 600-900 degrees Celsius. In some embodiments, if the substrate is annealed at higher temperatures it may be annealed for a duration of several minutes, and if the substrate is annealed at lower temperatures it may be annealed for a duration of several hours. In an embodiment, the substrate may be annealed at about 800 degrees Celsius for around 10 minutes. In other embodiments, different anneals may be performed.

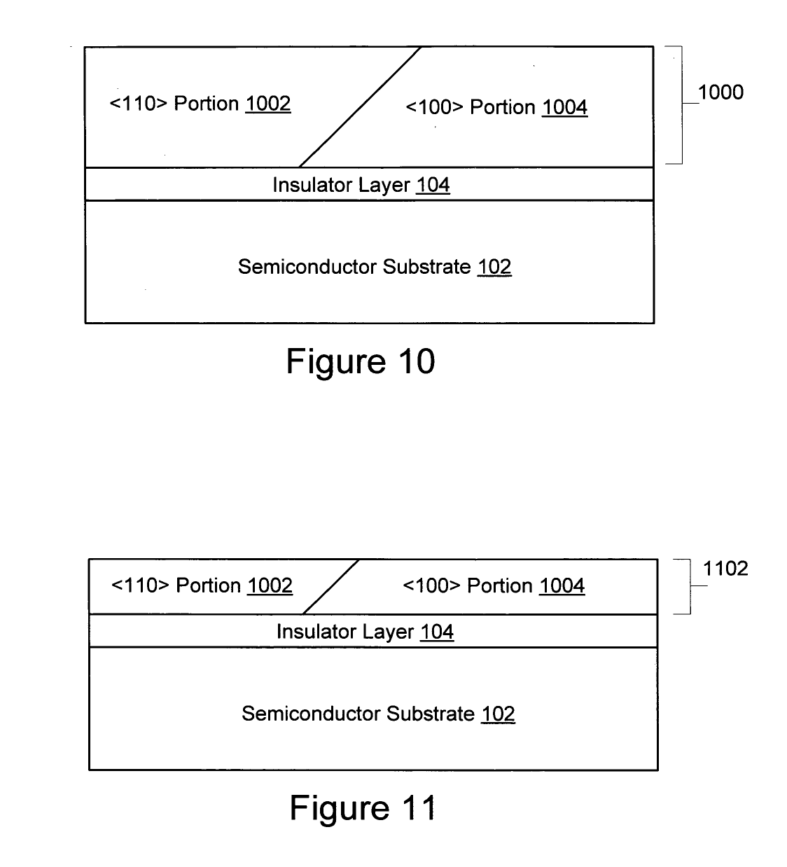

FIG. 10 is a cross sectional side view that illustrates the substrate after the amorphized regions 604, 704 have been recrystallized. The substrate may now be considered an SOI substrate, with a base semiconductor layer 102, an insulator (or buried oxide) layer 104, and a single top semiconductor (or device layer) layer 1000 with regions (or portions) 1002, 1004 having different crystal orientations. In the embodiment illustrated in FIG. 10, the substrate includes one or more <100> regions 1004 and one or more <110> regions 1002. Other embodiments may include different crystal orientations for the semiconductor portions 1002, 1004.

FIG. 11 is a cross sectional side view that illustrates the substrate after the semiconductor layer 1000 has been thinned. Any suitable method may be used to thin the device layer 1000. After thinning, the device layer 1000 may have a thickness 1102 appropriate to form devices, such as transistors, on. As another result of the thinning process, the junction between the different crystal orientations (the diagonal line in FIGS. 10 and 11) becomes smaller; it affects less of the area of the device layer 1000.

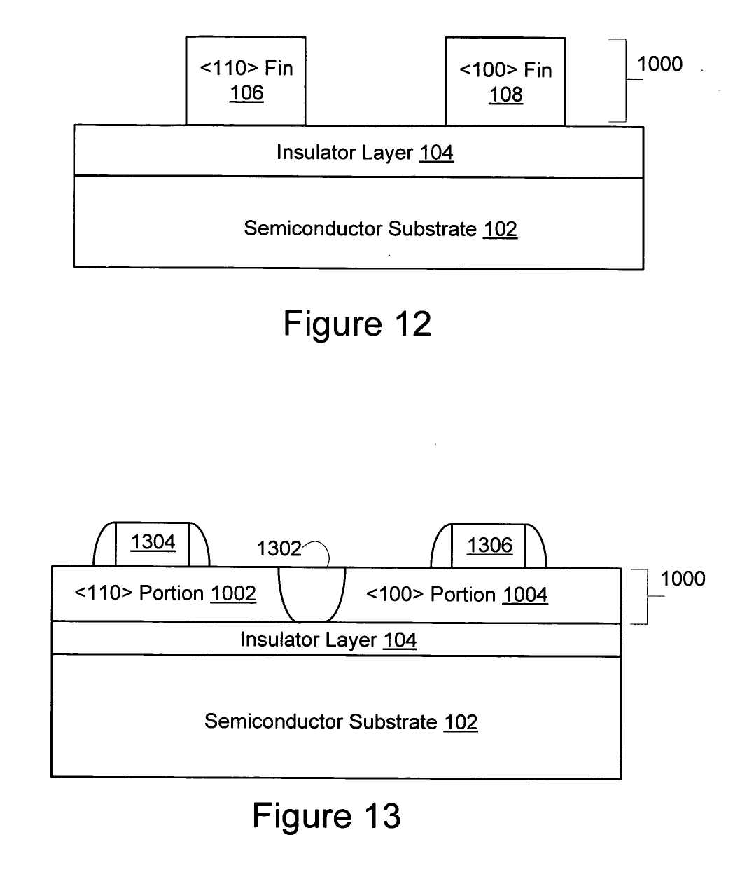

FIG. 12 is a cross sectional side view that illustrates the substrate after fins 106, 108 have been defined, on which tri-gate transistors may be formed. The fins 106, 108 may be formed by any suitable method. As shown in FIG. 12, defining the fins 106, 108 may also result in removing the junction between the portions 1002, 1004 of the device layer 1000. The fins 106, 108 may be considered semiconductor portions on the insulator layer 104, from which transistors, such as transistors 160, 170 of FIG. 1, may be formed. The fins 106, 108 may also be considered different regions of a top semiconductor layer of the SOI substrate. As each fin 106, 108 is defined from a different portion 1002, 1004 of the device layer 1000, each fin 106, 108 has a different crystal orientation; fin 106 has a <110> orientation and fin 108 has a <100> orientation. The rest of the transistor may then be formed to result in a device as illustrated in FIG. 1.

While the Figures and description above are concerned with tri-gate transistors, other types of transistors may also be formed. The transistors may be multi-gate or single gate, such as planar, transistors in some embodiments. As the device layer 1000 may have <100> and <110> portions (or other different crystal orientations), p-type and n-type transistors may both be formed on the device layer 1000, each with a crystal orientation to provide high performance for each type of transistor.

FIG. 13 is a cross sectional side view that illustrates one such device that includes planar transistor on a device layer having portions with different crystal orientations, according to another embodiment of the present invention. The device of FIG. 13 includes a semiconductor substrate 102, an insulator layer 104, and a device layer 1000. Together, these layers 102, 104, 1000 are an SOI substrate. There is a portion 1002 of the device layer 1000 with a <110> crystal orientation. A p-type planar transistor, including a gate electrode 1304, spacers, gate dielectric, and other regions is on the region 1002 with <110> crystal orientation. There is a portion 1004 of the device layer 1000 with a <100> crystal orientation. An n-type planar transistor, including a gate electrode 1306, spacers, gate dielectric, and other regions is on the region 1004 with <100> crystal orientation. An isolation region 1302, such as a shallow trench isolation region, may isolate the two transistors from each other. The isolation region 1302 may also remove the junction between the portions 1002, 1004 of the device layer 1000.

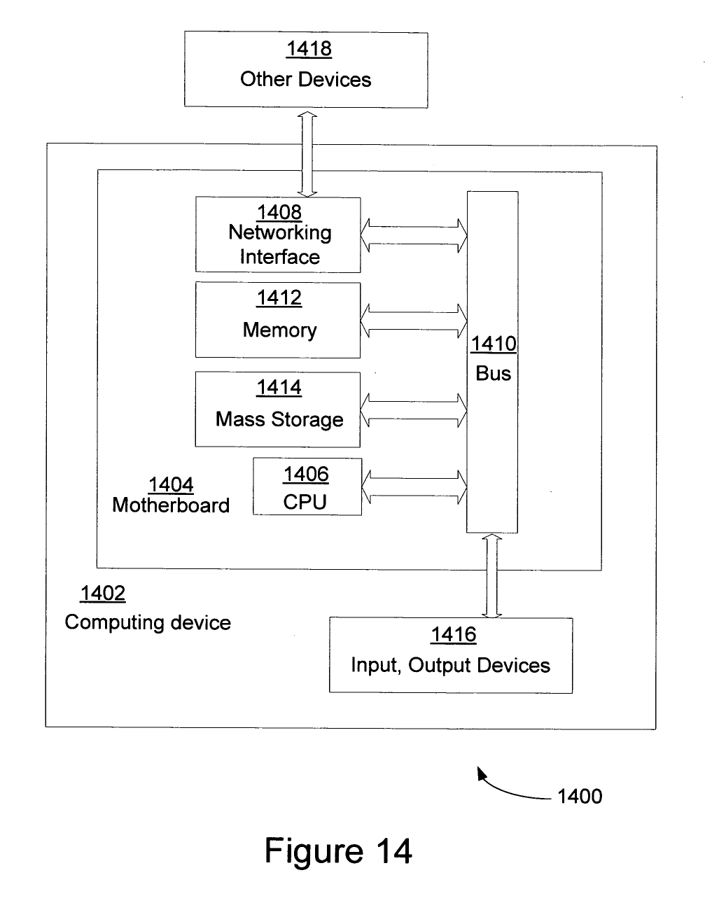

FIG. 14 illustrates a system 1400 in accordance with one embodiment of the present invention. One or more devices 100 formed with a device 1000 layer having regions 1002, 1004 with different crystal orientations as described above may be included in the system 1400 of FIG. 14. As illustrated, for the embodiment, system 1400 includes a computing device 1402 for processing data. Computing device 1402 may include a motherboard 1404. Coupled to or part of the motherboard 1404 may be in particular a processor 1406, and a networking interface 1408 coupled to a bus 1410. A chipset may form part or all of the bus 1410. The processor 1406, chipset, and/or other parts of the system 1400 may include one or more devices 100 formed from a device 1000 layer having regions 1002, 1004 with different crystal orientations.

Depending on the applications, system 1400 may include other components, including but are not limited to volatile and non-volatile memory 1412, a graphics processor (integrated with the motherboard 1404 or connected to the motherboard as a separate removable component such as an AGP or PCI-E graphics processor), a digital signal processor, a crypto processor, mass storage 1414 (such as hard disk, compact disk (CD), digital versatile disk (DVD) and so forth), input and/or output devices 1416, and so forth.

In various embodiments, system 1400 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

Any of one or more of the components 1406, 1414, etc. in FIG. 14 may include one or more devices 100 formed with lateral undercuts 114 as described herein. For example, transistors formed on a device 1000 layer having regions 1002, 1004 with different crystal orientations may be part of the CPU 1406, motherboard 1404, graphics processor, digital signal processor, or other devices.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A method for making a semiconductor device, comprising:
forming a substrate with a base layer of semiconductor material, a layer of insulator material on the base layer of semiconductor material, a first device layer of semiconductor material having a first crystal orientation on the layer of insulator material, and a second device layer of semiconductor material having a second crystal orientation different than the first crystal orientation on the first device layer of semiconductor material;
amorphizing a portion of the first device layer of semiconductor material, the amorphized portion of the first device layer of semiconductor material being under a non-amorphized portion of the second device layer of semiconductor material;
amorphizing a portion of the second device layer of semiconductor material, the amorphized portion of the second device layer of semiconductor material being on top of a non-amorphized portion of the first device layer of semiconductor material;
recrystallizing at least a portion of the amorphized portion of the first device layer of semiconductor material, the recrystallized portion having the second crystal orientation; and
recrystallizing at least a portion of the amorphized portion of the second device layer of semiconductor material, the recrystallized portion having the first crystal orientation.

2. The method of claim 1, wherein the base layer of semiconductor material, the first device layer of semiconductor material, and the second device layer of semiconductor material each comprise silicon, and wherein the first crystal orientation is <100> and the second crystal orientation is <110>.

3. The method of claim 1, wherein the base layer of semiconductor material, the first device layer of semiconductor material, and the second device layer of semiconductor material each comprise silicon, and wherein the first crystal orientation is <110> and the second crystal orientation is <100>.

4. The method of claim 1, further comprising removing portions of the device layers to form a first fin and a second fin on the layer of insulating material, wherein each of the first and second fins has a top surface and sidewalls, wherein the top surface and sidewalls of the first fin has the first crystal orientation and the top surface and sidewalls of the second fin has the second crystal orientation.

5. The method of claim 4, further comprising forming a first gate electrode on the top and sidewalls of the first fin, a channel region being beneath the first gate electrode within the first fin adjacent the top and the sidewalls.

6. The method of claim 5, wherein the first crystal orientation is <100> and the first fin, channel region, and first gate electrode are parts of an NMOS transistor.

7. The method of claim 6, further comprising forming a second gate electrode on the top and sidewalls of the second fin, a channel region being beneath the second gate electrode within the second fin adjacent the top and the sidewalls, wherein the second crystal orientation is <110> and the second fin, channel region, and second gate electrode are parts of a PMOS transistor.

8. The method of claim 1, further comprising:
forming a trench isolation region between a first region of the second device layer having the first crystal orientation and a second region of the second device layer having the second crystal orientation;
forming a PMOS transistor on the first region of the second device layer;
forming an NMOS transistor on the second region of the second device layer; and
wherein the first crystal orientation is <110> and the second crystal orientation is <100>.

9. A semiconductor device, comprising:
a semiconductor substrate;
an insulator layer on the semiconductor substrate;
a first semiconductor portion on the insulator layer, the first semiconductor portion having a top surface, the top surface having a crystal structure with a <100> crystal orientation; and
a second semiconductor portion on the insulator layer, the second semiconductor portion having having a top surface, the top surface having a crystal structure with a <110> crystal orientation.

10. The device of claim 9, wherein the first semiconductor portion has side walls, the side walls of the first semiconductor portion having a crystal structure with a <100> crystal orientation and the second semiconductor portion has side walls, the side walls of the second semiconductor portion having a crystal structure with a <110> crystal orientation.

11. The device of claim 10, further comprising:
a first gate electrode on the top surface and side walls of the first semiconductor portion, wherein the first gate electrode and first semiconductor portion are parts of an NMOS transistor; and
a second gate electrode on the top surface and side walls of the second semiconductor portion, wherein the second gate electrode and second semiconductor portion are parts of a PMOS transistor.

12. The device of claim 9, further comprising a trench isolation region between the first and second semiconductor portions.

13. The device of claim 12, further comprising:
a first gate electrode and source and drain regions on the first semiconductor portion, the first gate electrode and source and drain regions being part of an NMOS transistor; and
a second gate electrode and source and drain regions on the second semiconductor portion, the second gate electrode and source and drain regions being part of a PMOS transistor.

14. The device of claim 9, wherein each of the semiconductor substrate, the first semiconductor portion, and the second semiconductor portion comprises silicon.

15. The device of claim 9, wherein the first semiconductor portion has a first concentration of a dopant at a first depth, and the second semiconductor portion has a second concentration of the dopant at a second depth.

16. The device of claim 15, wherein the first depth is deeper than the second depth.

17. A semiconductor device, comprising:
a semiconductor on insulator substrate; and
wherein a top semiconductor layer of the semiconductor on insulator substrate has a first region with a crystalline structure with a first orientation and a second region a crystalline structure with a second crystal orientation different than the first crystal orientation.

18. The device of claim 17, further comprising a P-type transistor on the first region and an N-type transistor on the second region.

19. The device of claim 18, wherein each of the P-type and N-type transistors is a multi-gate transistor with a gate electrode formed on a top surface and side walls of a portion of the top semiconductor layer.

20. The device of claim 17, wherein the first orientation is <100> and the second orientation is <110>.
